(19) United States
(12) Patent Application Publication
(10) Pub. No.: US 2012/0160154 A1
(43) Pub. Date: Jun. 28, 2012

(54) Method For Producing Silicon Single Crystal Ingot

(75) Inventors: Hideo Kato, Hikari (JP); Hideaki Murakami, Hikari (JP)

(73) Assignee: SILTRONIC AG, Munich (DE)

(21) Appl. No.: 13/329,378

(22) Filed: Dec. 19, 2011

(30) Foreign Application Priority Data
Dec. 28, 2010 (JP) 2010-293964

(51) Int. Cl. C30B 15/14

(52) U.S. Cl. 117/13

(57) ABSTRACT

An ingot production method which makes it possible to greatly restrict formation of pinholes or substantially prevent them avoids the use of substantial amounts of small-sized polycrystalline silicon chunks of polycrystalline silicon chunks, only middle-sized polycrystalline silicon chunks and large-sized polycrystalline silicon chunks. In the step of filling polycrystalline silicon, the polycrystalline silicon chunks are randomly supplied into the crucible.

### CROSS-REFERENCE TO RELATED APPLICATIONS

This application claims priority to Japanese Patent Application No. JP 2010293964 filed Dec. 28, 2010 which is herein incorporated by reference.

### BACKGROUND OF THE INVENTION

1. Field of the Invention

The present invention relates to a method for producing a silicon single crystal ingot (herein after referred to as an “ingot”) using the Czochralski method (hereinafter referred to as the “CZ method”), and, particularly, to a method for filling a crucible with polycrystalline silicon raw material.

2. Background Art

Single crystal silicon wafer semiconductor substrates for producing semiconductor devices are commonly processed from ingots grown by the CZ method. In the CZ method, a crucible is filled with polycrystalline silicon which is then melted to obtain a silicon melt. Next, a seed crystal is brought into contact with the silicon melt and an ingot is grown by pulling up the seed crystal. In this process, bubbles contained in the silicon melt do not escape from the surface of the silicon melt, but remain in the silicon melt. These bubbles may then be incorporated into the ingot, forming pinholes which are cavities derived from the bubbles, in the grown ingot. Silicon wafers are produced by slicing the ingot, and there is thus the problem that semiconductor devices having the desired configuration cannot be produced from a wafer in which pinholes have been formed.

In order to reduce the formation of pinholes during the growth of the ingot, various methods have been conventionally proposed. For example, a method of melting polycrystalline silicon material at a furnace pressure of 5-60 mbar to reduce generation of pinholes has been disclosed. See e.g. Japanese Patent Application Publication (Kokai) No. H5-9097. A method has been also disclosed in which chunks of polycrystalline silicon material are divided into three classes depending on their sizes, the large chunks are arranged along the side surface of a crucible, the small chunks are arranged at the center of the crucible, and the medium chunks are arranged on these small chunks to reduce generation of pinholes. See e.g. Japanese Patent Application Publication (Kokai) No. 2002-535223. Further, there has been disclosed a method in which the crucible axis supporting the crucible is oscillated between the steps of melting the polycrystalline silicon and growth of the ingot by bringing a seed crystal into contact with the silicon melt, thereby reducing generation of pinholes. See e.g. Japanese Patent Application Publication (Kokai) No. 2007-210803.

Recently, semiconductor devices have become finer and their thickness has been reduced as well, and thus during manufacture of semiconductor devices, pinholes formed in the ingot have become a more serious problem. In addition, many hours of labor are required for inspecting the ingot for pinholes. For these reasons, pinholes need to be further reduced, but the conventional methods discussed previously have been insufficient.

### SUMMARY OF THE INVENTION

An object of the present invention is to provide a method for producing an ingot which makes it possible to greatly restrict and substantially prevent the formation of pinholes. These and other objects are surprisingly and unexpectedly achieved by producing the silicon melt from large chunks of polycrystalline silicon, a majority of the chunks of silicon having a size greater than 50 mm, and the remainder having a size from 20 to 50 mm.

### BRIEF DESCRIPTION OF THE DRAWINGS

FIG. 1 is a view showing a conventional method for filling a crucible with polycrystalline silicon in the CZ method.

FIG. 2 is a view showing a method for filling a crucible with polycrystalline silicon for producing an ingot according to one embodiment of the present invention.

FIG. 3 is a view showing kinds of polycrystalline silicon chunks as raw materials.

FIG. 4 is a graph showing the relative rates of pinhole generation between Embodiments 1, 2 according to the present invention and Comparative Example 1.

### DETAILED DESCRIPTION OF THE PREFERRED EMBODIMENT(S)

In achieving the sought for reduction of pinholes, the inventor performed extensive research directed to an ingot producing method which makes it possible to greatly restrict formation of pinholes and substantially prevent it. Without wishing to be bound to any particular theory, it was assumed that the cause of pinhole generation lay in small bubbles of at most 1 mm remaining in the silicon melt. Concretely, bigger bubbles have large buoyancy, rise up to the surface of silicon melt, and immediately disappear. However, since small bubbles have small buoyancy and are caught by the convective flow of the silicon melt, the small bubbles remain in the melt, and these residual bubbles are taken up in the crystal while the ingot is grown. The inventor theorized that the reason why the small bubbles remain in the silicon melt is because the bubbles are formed on the surface of the polycrystalline silicon raw material during the process of melting. The melting process thus continues with these bubbles adhering to the surface of the polycrystalline silicon, and these bubbles are taken up in the convective flow of the silicon melt. The inventor thus discovered that if the ratio of the surface area of the polysilicon charge to the weight of the charge, i.e. the ratio of the total surface area to the total weight of the chunks of polycrystalline silicon, is reduced, the generation of pinholes can be drastically restricted, and can even be substantially prevented in the grown ingot.

In order to achieve pinhole reduction, the method for producing an ingot according to the present invention comprises a filling step of filling a crucible with polycrystalline silicon, a melting step of melting the polycrystalline silicon to form a silicon melt in the crucible, and a pulling up step of bringing a seed crystal into contact with the silicon melt and pulling up the seed crystal to thereby grow an ingot, wherein, in the filling step, the crucible is randomly filled with polycrystalline silicon, the polycrystalline silicon being in the form of large-sized chunks of polycrystalline silicon.

In the method for producing an ingot according to the present invention, the large-sized chunks of polycrystalline silicon consist of chunks of polycrystalline silicon with a size of at least 20 mm, and the large-sized chunks of polycrystalline silicon include chunks of polycrystalline silicon of at least one of polycrystalline silicon chunks with a size of more than 50 mm and polycrystalline silicon chunks with a size of 20 mm to 50 mm. In one embodiment, the supplied chunks of polycrystalline silicon include at least chunks of polycrystalline silicon with a size of more than 50 mm. In a second embodiment, the supplied chunks of polycrystalline silicon include at least the chunks of polycrystalline silicon with a size of 20 mm to 50 mm.

In a preferred embodiment of the present invention, the large-sized chunks of polycrystalline silicon consist of chunks of polycrystalline silicon with a size of more than 50 mm and chunks of polycrystalline silicon with a size of 20 mm to 50 mm, and the concentration of the chunks of polycrystalline silicon with a size of more than 50 mm is 70% by weight, while the concentration of the chunks of polycrystalline silicon with a size of 20 mm to 50 mm is 30% by weight.

In the inventive method for filling a crucible with polycrystalline silicon, since large-sized chunks of polycrystalline silicon are supplied to the crucible, it is possible to reduce the ratio of the surface area to the weight of the polycrystalline silicon, and to greatly restrict the adherence of the bubbles to the polycrystalline silicon when the filled polycrystalline silicon is melted, in comparison with the prior art. Thus, it is possible to greatly restrict the problem of bubbles being taken up into the melt and remaining in the melt. Accordingly, it is also possible to greatly restrict or substantially prevent formation of pinholes in the grown ingot in comparison with the methods of the prior art.

In this manner, in the filling step, irrespective of arrangement of chunks of polycrystalline silicon in the crucible as in the prior art, the chunks of polycrystalline silicon can be randomly supplied to the crucible. As a result, the filling step can be made simple and trouble-saving.

The present invention will be described in detail below with reference to the drawings, showing preferred embodiments thereof.

According to the CZ method, a crucible is filled with polycrystalline silicon as raw materials. Then, in an atmosphere of inert gas, e.g. Ar gas, the polycrystalline silicon filled in the crucible is melted to form a silicon melt, a seed crystal is brought into contact with this silicon melt, and the seed crystal brought into contact with the silicon melt is pulled up, so that an ingot is grown.

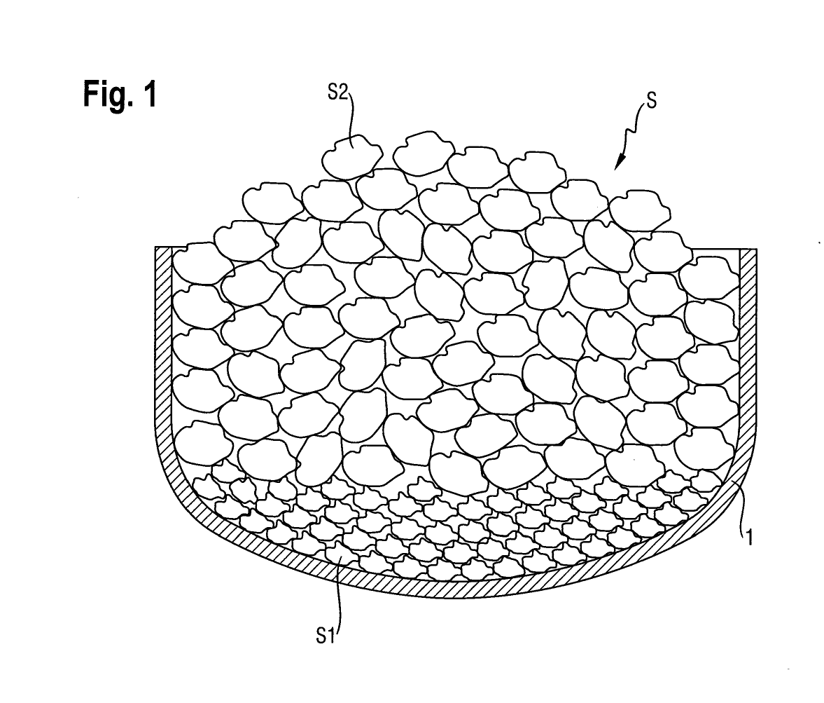

FIG. 1 is a view showing a conventional method for filling a crucible with polycrystalline silicon raw material in the CZ method. As shown in FIG. 1, a crucible 1 is filled with a plurality of polycrystalline silicon chunks S which are the chunks of polycrystalline silicon used in the conventional method. The polycrystalline silicon chunks include small-sized polycrystalline silicon chunks S1 having a small chunk size and middle-sized polycrystalline silicon chunks S2 having a middle chunk size. The small-sized polycrystalline silicon chunks S1 and the middle-sized polycrystalline silicon chunks S2 are polycrystalline silicon chunks of the size which have been generally used in the CZ method.

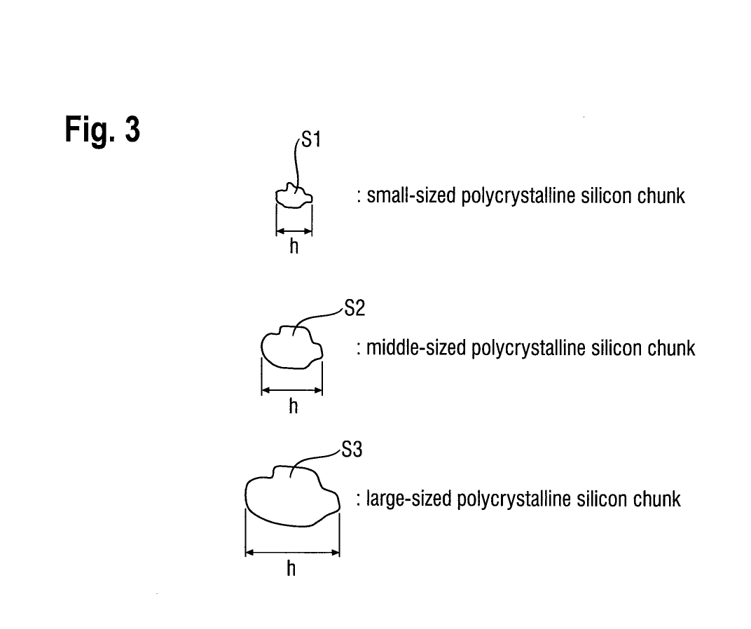

As shown in FIG. 3, the size of the polycrystalline silicon chunks S is defined on the basis of their maximum width h. The small-sized polycrystalline silicon chunks S1 are polycrystalline silicon chunks having the maximum width h of less than 20 mm, and the middle-sized polycrystalline silicon chunks S2 are polycrystalline silicon chunks having the maximum width h from 20 mm to 50 mm.

As shown in FIG. 1, in the conventional method for filling polycrystalline silicon, because of their size, the small-sized polycrystalline silicon chunks S1 are deposited in the lower portion of the crucible 1, and the middle-sized polycrystalline silicon chunks S2 are deposited on these small-sized polycrystalline silicon chunks S1. From the viewpoint of cost reduction due to an increase in ingot size, a high rate of filling a crucible with polycrystalline silicon chunks is required. In conventional methods for filling polycrystalline silicon, polycrystalline silicon chunks of a large size have never been actively filled.

The crucible 1 is, for example, a crucible made of quartz and is provided within a furnace which is not shown in the drawing. The crucible 1 filled with the polycrystalline silicon chunks S is exposed to an inert gas atmosphere, e.g. an Ar (argon) gas atmosphere.

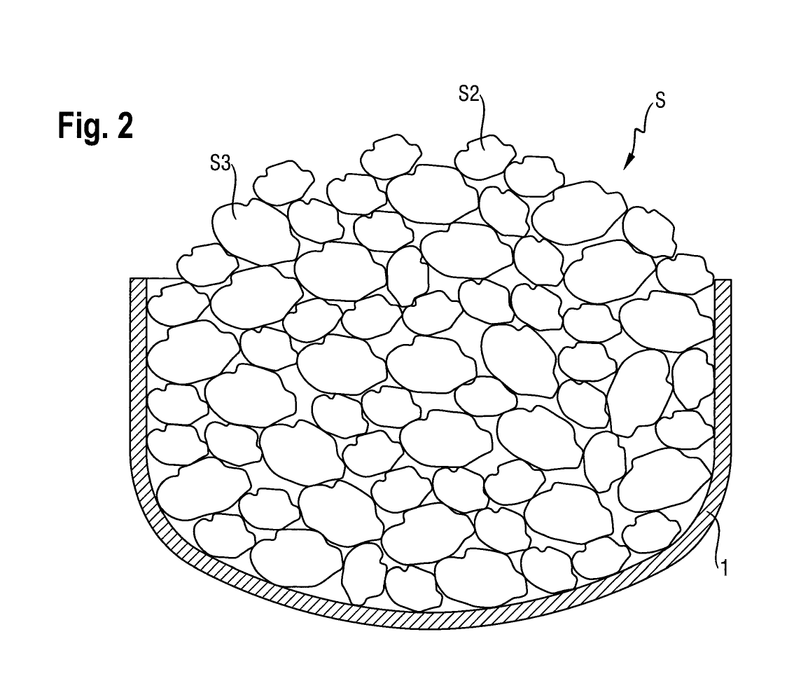

FIG. 2 is a view showing a method for filling a crucible with polycrystalline silicon in a method for producing an ingot according to one embodiment of the present invention. As shown in FIG. 2, in the step of filling polycrystalline silicon, the small-sized polycrystalline silicon chunks S1 are not used as the supplied polycrystalline silicon chunks S. Only the middle-sized polycrystalline silicon chunks S2 and large-sized polycrystalline silicon chunks S3 are used. As shown in FIG. 3, the large-sized polycrystalline silicon chunks S3 are the polycrystalline silicon chunks having a maximum width h of more than 50 mm.

In the step of filling polycrystalline silicon in the present embodiment, the polycrystalline silicon chunks S are randomly supplied into the crucible 1. Namely, the polycrystalline silicon chunks S are supplied into the crucible 1 without considering the arrangement of the polycrystalline silicon chunks S as well as the arrangement and distribution, etc. of the middle-sized polycrystalline silicon chunks S2 and the large-sized polycrystalline silicon chunks S3. For example, by inclining a container, in which the polycrystalline silicon chunks S are randomly deposited, the polycrystalline silicon chunks S are randomly supplied into the crucible 1.

As shown in FIG. 2, in the method for filling the polycrystalline silicon chunks S in the present embodiment, the size of the polycrystalline silicon chunks S to be filled is larger than in the case of the conventional method for filling the polycrystalline silicon chunks S shown in FIG. 1. For this reason, in the filling method in the present embodiment, the ratio of the total surface area of the polycrystalline silicon chunks S to be filled to the total weight of the polycrystalline silicon chunks S to be filled, can be made smaller than in the case of the conventional filling method in FIG. 1. Therefore, as described above, it is possible to drastically restrict and substantially prevent formation of pinholes in an ingot to be grown in comparison with the prior art.

In the method for producing an ingot according to the present embodiment, the polycrystalline silicon chunks S filled in the crucible 1 consist of the large-sized polycrystalline silicon chunks S3 and the middle-sized polycrystalline silicon chunks S2. However, the polycrystalline silicon chunks S are not limited to the above. The polycrystalline silicon chunks S just have to contain polycrystalline silicon chunks of at least the size of the middle-sized polycrystalline silicon chunks S2. Further, as described above, it is preferable that the polycrystalline silicon chunks S to be filled have a large size, and it is preferable that, in the polycrystalline silicon chunks S to be filled in the crucible 1, the ratio of the large-sized polycrystalline silicon chunks S3 to the middle-sized polycrystalline silicon chunks S2 is high. However, the maximum size of the large-sized polycrystalline silicon chunks S3 is a size at which the chunks still can be filled into the crucible.

### EXAMPLES

Examples of the present invention will be explained below. By using the method for producing an ingot according to the present embodiment, ingots were grown from two kinds of polycrystalline silicon chunks S as the raw materials (Examples 1 and 2).

In Example 1, the following polycrystalline silicon chunks S were used as the raw materials: The content ratio (weight distribution) of the middle-sized polycrystalline silicon chunks S2 and the large-sized polycrystalline silicon chunks S3 was the middle-sized polycrystalline silicon chunks S2: 100% by weight and the large-sized polycrystalline silicon chunks S3: 0% by weight.

In Example 2, the following polycrystalline silicon chunks S were used as the raw materials: The content ratio of the middle-sized polycrystalline silicon chunks S2 and the large-sized polycrystalline silicon chunks S3 was the middle-sized polycrystalline silicon chunks S2: 30% by weight and the large-sized polycrystalline silicon chunks S3: 70% by weight.

As a comparative example, by using the conventional method for filling polycrystalline silicon shown in FIG. 1, an ingot was produced (Comparative Example 1). In Comparative Example 1, the following polycrystalline silicon chunks S were used as the raw materials: The content ratio of the small-sized polycrystalline silicon chunks S1 and the middle-sized polycrystalline silicon chunks S2 was the small-sized polycrystalline silicon chunks S1: 30% by weight and the middle-sized polycrystalline silicon chunks S2: 70% by weight.

In above Examples 1, 2 and Comparative Example 1, the total weights of the polycrystalline silicon chunks S as the raw materials were identical with each other and amounted to 130 kg. Further under the same production conditions, ingots were grown by the CZ method. Incidentally, in the quartz crucible, bubbles derived from the quartz crucible itself are included, since in growing an ingot bubbles may be emitted from the quartz crucible into silicon melt. Therefore, this can also cause generation of pinholes. In the present examples and in Comparative Example 1, quartz crucibles all having the same quality levels were used, and therefore it can be considered that the influence of the quartz crucibles does not impact the rates of generation of pinholes.

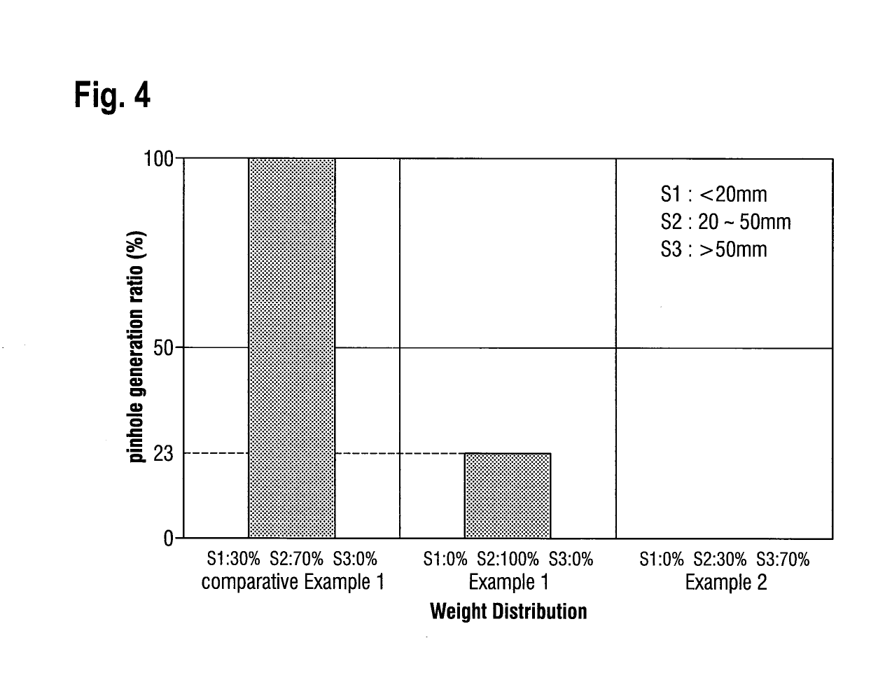

Ten ingots having a length of about 1500 mm grown in Examples 1, 2 and Comparative Example 1 were sliced to produce silicon wafers. For each silicon wafer produced in accordance with Examples 1, 2 and Comparative Example 1, a pinhole test was conducted. The pinhole test was a total amount test by visual observation. The test results are shown in FIG. 4.

FIG. 4 shows a relative ratio of pinhole generation rates with respect to Comparative Example 1. As shown in FIG. 4, in Example 1, it can be seen that the generation of pinholes can be reduced by 77% in comparison with the Comparative Example 1. In Example 2, no pinholes are observed and the pinhole generation rate is 0%.

Example 2 has the largest percentage of the large-sized polycrystalline silicon chunks S included in all polycrystalline silicon chunks S filled in the crucible 1, and Example 1 has the second largest percentage of the large-sized polycrystalline silicon chunks S. Comparative Example 1 has the smallest percentage of the large-sized polycrystalline silicon chunks S included in all the polycrystalline silicon chunks S filled in the crucible 1. Namely, Example 2 has the smallest ratio (weight to surface-area ratio) of the total surface area of the filled polycrystalline silicon chunks S in the crucible 1 to the total weight of the polycrystalline silicon chunks S filled in the crucible 1, Example 1 has the second smallest weight to surface-area ratio, and Comparative Example 1 has the largest weight to surface-area ratio. As described above, FIG. 4 clarifies that the more the polycrystalline silicon chunks filled in the crucible 1 during the filling step contain the large-sized polycrystalline silicon chunks, the lower the pinhole generation rate becomes.

As described above, in the method for producing an ingot according to the present embodiment, the size of the polycrystalline silicon chunks S to be filled into the crucible 1 is large, and by the method for filling according to the present embodiment, the ratio of the total surface area of the polycrystalline silicon chunks S to be filled to the total weight of the polycrystalline silicon chunks S to be filled into the crucible 1, can be made smaller. For this reason, it is possible to drastically restrict the number of the pinholes formed in the ingot thus produced in comparison with the conventional art, and to substantially prevent them.

By increasing the size of the polycrystalline silicon chunks S to be filled into the crucible 1, the method for producing an ingot of the present invention makes it possible for the polycrystalline silicon chunks S to be randomly supplied into the crucible 1 during the step of filling. Thus, a simple, uncomplicated step of filling can be achieved. For this reason, a method for producing an ingot that is simple and uncomplicated in comparison with the conventional art can be achieved, and the production costs can be reduced.

It should be noted that the present invention is not limited to the above embodiments. Rather, the above embodiments and examples are examples included in the present invention. For example, the distribution of the sizes of the polycrystalline silicon chunks S as the raw materials filled in the crucible 1 is not limited to those described above. Further, the method for producing an ingot is not limited to the above method and can be applied to the MCZ method using a magnetic field, and to materials other than silicon.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A method for producing a silicon single crystal ingot, comprising a filling step of filling a crucible with polycrystalline silicon, a melting step of melting the filled polycrystalline silicon to form a silicon melt in the crucible, and a pulling up step of bringing a seed crystal into contact with the silicon melt and pulling up the seed crystal brought into contact, to thereby grow an ingot,
wherein, in the filling step, the crucible is filled with the polycrystalline silicon in the form of a plurality of chunks of polycrystalline silicon randomly supplied to the crucible, and the chunks of polycrystalline silicon are large-sized chunks of polycrystalline silicon.

2. The method of claim 1, wherein the large-sized chunks of polycrystalline silicon consist essentially of chunks of polycrystalline silicon with a size of at least 20 mm, and the large-sized chunks of polycrystalline silicon include chunks of polycrystalline silicon with a size of 20 mm to 50 mm.

3. The method of claim 2, wherein the chunks of polycrystalline silicon further include chunks of polycrystalline silicon with a size of greater than 50 mm.

4. The method of claim 2, wherein the supplied chunks of polycrystalline silicon consist essentially of chunks of polycrystalline silicon with a size of 20 mm to 50 mm.

5. A method for producing a silicon single crystal ingot according to claim 2, wherein the large-sized chunks of polycrystalline silicon consist essentially of chunks of polycrystalline silicon with a size of more than 50 mm and chunks of polycrystalline silicon with a size of 20 mm to 50 mm, and the weight percentage of chunks of polycrystalline silicon with a size of more than 50 mm is about 70% by weight, while the weight percentage of the chunks of polycrystalline silicon with a size of 20 mm to 50 mm is 30% by weight, the weight percentages based on the total weight of polycrystalline silicon in the crucible.

6. The method of claim 1, wherein the weight percentage of polycrystalline silicon chunks having a size of less than 20 mm is reduced in proportion to polycrystalline silicon chunks having a size greater than 20 mm such that an ingot grown from a melt of the polycrystalline silicon is substantially free of pinholes.
